(19) United States
(12) Patent Application Publication
(10) Pub. No.: US 2011/0109333 A1
(43) Pub. Date: May 12, 2011

(54) Detection of Water Ingress to an Apparatus by Resistance Measurements Between Two Electrodes

(76) Inventors: Niko Santeri Porjo, Piikkio (FI); Barry Fredrick Rowland, Salo (FI); Jakke Makela, Turku (FI)

(21) Appl. No.: 12/933,134

(22) PCT Filed: Mar. 20, 2008
(86) PCT No.: PCT/EP2008/053426

§ 371 Date: Dec. 13, 2010

(51) Int. Cl. G01R 27/08

(52) U.S. Cl. 324/694

(57) ABSTRACT

An apparatus including a first electrical arrangement that has a resistance between a first electrode and a second electrode in the absence of water and has a different resistance between the first electrode and the second electrode in the presence of water; a mechanical arrangement configured to maintain the presence of water at the first electrical arrangement; and a detecting electrical arrangement configured to detect a change in the resistance of the first electrical arrangement.

### FIELD OF THE INVENTION

Embodiments of the present invention relate to detecting water ingress to an apparatus.

### BACKGROUND TO THE INVENTION

Electrical and electronic apparatus may malfunction if the electrical components become wet. This problem may be addressed by sealing a housing of the apparatus to prevent water ingress. However, it may not be possible or desirable to completely seal an apparatus.

When an apparatus malfunctions it would desirable to detect whether the malfunction is a result of water ingress to the apparatus.

### BRIEF DESCRIPTION OF VARIOUS EMBODIMENTS OF THE INVENTION

According to various embodiments of the invention there is provided an apparatus comprising: a first electrical arrangement that has a first resistance between a first electrode and a second electrode in the absence of water and has a second resistance between the first electrode and the second electrode in the presence of water; a mechanical arrangement configured to maintain the presence of water at the first electrical arrangement; and a detecting electrical arrangement configured to detect a change in the resistance of the first electrical arrangement.

According to various embodiments of the invention there is provided a method comprising: determining an electrical resistance of an electrical arrangement that is provided to detect ingress of water to an electronic apparatus; and determining the ingress of water if the determined electrical resistance varies.

According to various embodiments of the invention there is provided an apparatus comprising: a first electrical arrangement that has a resistance between a pair of electrodes in the absence of water and a different resistance between the pair of electrodes in the presence of water; a second electrical arrangement, distinct from the first electrical arrangement and connected in electrical parallel with the first electrical arrangement, that has a resistance between a pair of electrodes in the absence of water and has a different resistance between the pair of electrodes in the presence of water;

and a detecting electrical arrangement configured to detect a change in the resistance of the first electrical arrangement or a change in the resistance of the second electrical arrangement.

According to various embodiments of the invention there is provided an apparatus comprising: a first electrical arrangement that has a resistance between a first electrode and a second electrode in the absence of water and has a different resistance between the first electrode and the second electrode in the presence of water; a detecting electrical arrangement configured to detect a change in the resistance of the first electrical arrangement; and a further electrical arrangement configured to encourage, when activated, the absence of water at the first electrical arrangement.

According to various embodiments of the invention there is provided an electrical arrangement comprising: a first electrode and a second electrode and having a resistance between the first electrode and the second electrode in the absence of water and a different resistance between the first electrode and the second electrode in the presence of water; and an electrical element configured to encourage, when activated, the absence of water between the first electrode and the second electrode.

According to various embodiments of the invention there is provided an apparatus comprising: a third electrical arrangement configured to provide a constant voltage between pairs of separated electrodes, wherein the pairs of electrodes have a first mechanical configuration in the absence of a corrosive atmosphere and have a deteriorated, second mechanical configuration after prolonged exposure to a corrosive atmosphere.

According to various embodiments of the invention there is provided an apparatus comprising: an electrical and mechanical arrangement configured to detect voiding of a warranty by electrically identifying water ingress.

According to various embodiments of the invention there is provided a method comprising: providing a first electrical arrangement that has a resistance between a first electrode and a second electrode in the absence of water and has a different resistance between the first electrode and the second electrode in the presence of water; providing a mechanical arrangement configured to maintain the presence of water at the first electrical arrangement; and providing a detecting electrical arrangement configured to detect a change in the resistance of the first electrical arrangement.

### BRIEF DESCRIPTION OF THE DRAWINGS

For a better understanding of various embodiments of the present invention reference will now be made by way of example only to the accompanying drawings in which:

FIGS. 1A and 1B schematically illustrate an electrical arrangement;

FIGS. 2A, 2B, 3A, 3B, 4A, 4B, 5A, 5B, 6A, 6B illustrate various mechanical arrangements configured to enable the ingress of water to the electrical arrangement;

FIG. 7 illustrates an electrical arrangement for detecting prolonged exposure to a corrosive atmosphere;

FIG. 8 schematically illustrates how multiple electrical arrangements may be electrically interconnected as parallel elements in a larger scale electrical arrangement;

FIG. 9 schematically illustrates an apparatus comprising one example of a detecting electrical arrangement and an electrical arrangement;

FIG. 10 schematically illustrates an apparatus comprising another example of a detecting electrical arrangement and an electrical arrangement;

FIG. 11 schematically illustrates an apparatus comprising an example of a differential detecting electrical arrangement;

FIG. 12 schematically illustrates an apparatus using, in this example, a differential detecting electrical arrangement and re-using an LCD driver; and

FIG. 13 schematically illustrates an electronic device that comprises an interface that enables an external device to test for water ingress.

### DETAILED DESCRIPTION OF VARIOUS EMBODIMENTS OF THE INVENTION

The figures schematically illustrate an apparatus comprising an electrical arrangement 2 that has a high resistance between a first electrode 1 and a second electrode 3 in the absence of water and has a low resistance between the first electrode 1 and the second electrode 3 in the presence of water; a mechanical arrangement 2A, 2B, 2C configured to maintain the presence of water at the electrical arrangement 2; and a detecting electrical arrangement 51 configured to detect a change in the resistance of the electrical arrangement 2.

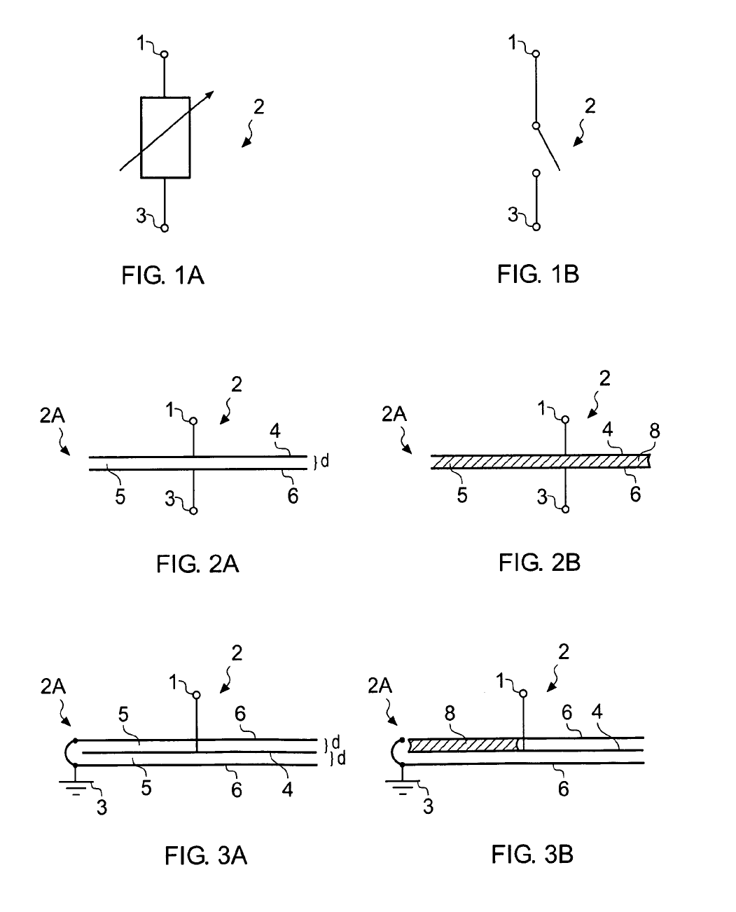

FIGS. 1A and 1B schematically illustrate an electrical arrangement 2 that has a high resistance between a first electrode 1 and a second electrode 3 in the absence of water interconnecting the electrodes and has a low resistance between the first electrode 1 and the second electrode 3 in the presence of water between the electrodes. In FIG. 1A, the electrical arrangement 2 is illustrated as a variable resistor, the resistance of which decreases significantly in the presence of water. In FIG. 1B, the electrical arrangement 2 is illustrated as a switch which is shorted in the presence of water.

FIGS. 2A to 6B illustrate various electro-mechanical arrangements 2A, 2B, 2C configured to enable the ingress of water to the electrical arrangement 2 and to maintain the presence of water at the electrical arrangement 2.

FIG. 2A illustrates an example of a suitable mechanical arrangement 2A. In this example, the first electrode forms a first conductive strip 4 and the second electrode 3 forms a second conductive strip 6 which is arranged parallel to the first conductive strip 4. The first and second conductive strips 4, 6 are separated by a narrow gap and they form a volume 5 that retains liquid water 8 by capillary action, as illustrated in FIG. 2B.

The first and second conductive strips 4, 6 may travel together within an apparatus as, for example, illustrated in FIG. 12. They may bend and bifurcate in unison so that they extend to the most likely positions of water ingress. It is of course important that the strips do not make permanent electrical contact.

FIG. 3A illustrates another example of the mechanical arrangement 2A. In this example, the first electrode forms a first conductive strip 4 and the second electrode 3 forms a pair of electrically interconnected second conductive strips 6 which are arranged in parallel to each other and also in parallel to and on either side of the first conductive strip 4. The first conductive strip 4 is separated from a second conductive strip 6 on one side by a narrow gap and is separated from a second conductive strip 6 on the other side by another narrow gap. The narrow gaps form volumes 5 that can retain liquid water 8 by capillary action, as illustrated in FIG. 3B.

The ‘sandwiching’ of the first conductive strip 4 between the parallel second conductive strips 6 forms an electrical arrangement that reduces interference. The first and second conductive strips 4, 6 may travel together within an apparatus. They may bend and bifurcate in unison so that they extend to the most likely positions of water ingress. It is of course important that the strips do not make permanent electrical contact.

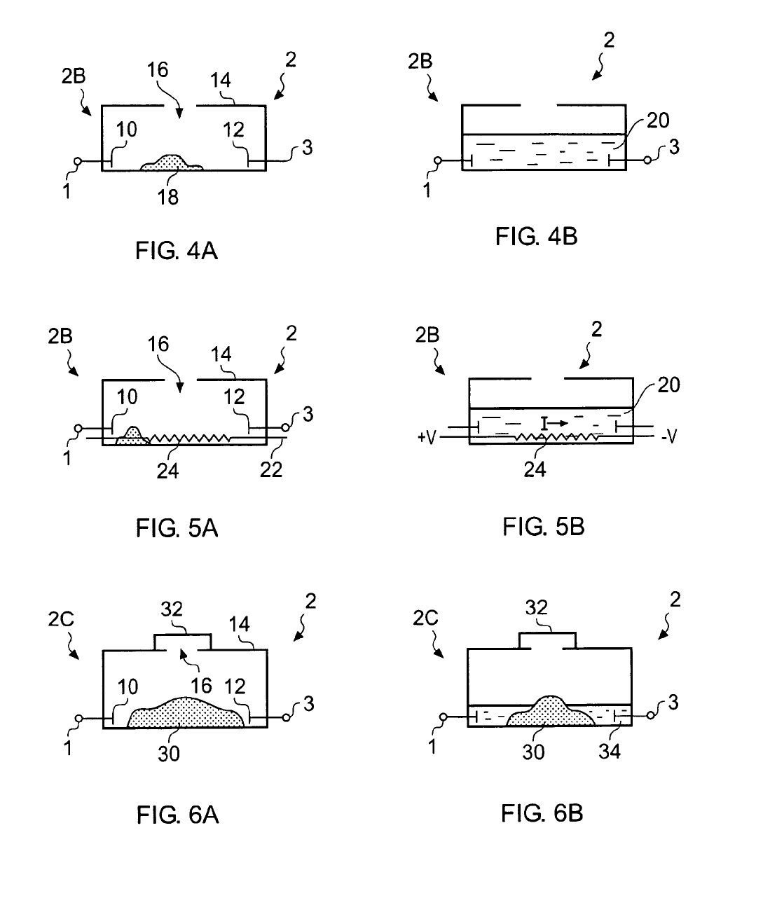

FIG. 4A illustrates another example of a suitable mechanical arrangement 2B. The mechanical arrangement 2B comprises a substantially enclosed housing 14 having an aperture 16. The aperture 16 is a hole through the housing and may be sized to enable the ingress of water liquid and/or water vapor and restrict the evaporation of water. The size and depth of the aperture 16 may be designed to enable liquid water to enter the housing by capillary action.

The housing 14 comprises a compound 18 that at least partially dissolves in water to form an aqueous solution of ions. The compound is typically a soluble salt or a collection soluble salts. One example of a suitable compound is sodium chloride NaCl. Another example of a commercially available compound is Seltin (trade mark) which comprises NaCl 50%, KCl 40%, 10% magnesium and iodine salts.

When the water enters the housing 14, it dissolves the compound 18 and forms a conductive solution 20 that interconnects the first and second electrodes.

FIG. 5A illustrates the use of a further electrical arrangement 24 that is configured to promote, when activated, the removal of water at the electrical arrangement 2.

In this example, a resistive element 24 is placed in a low-lying position within the housing 14. When a potential difference is applied across the resistive element 24, a current flows through the resistive element 24 producing heat.

The heat warms the conductive solution 20 and promotes evaporation of water through the aperture 16. The evaporation of all of the water results in the compound 18 being recovered as illustrated in FIG. 5A. At this point, the potential difference may be removed from across the resistive element 24. Whether a potential difference is applied across the resistive element and the size of that potential difference may be determined by the value of a resistance measured between the first electrode 1 and the second electrode 3. The resistive element 24 should also be electrically insulated from the conductive solution 20.

If a resistive element 24 is present in a mobile apparatus, for example a mobile cellular telephone, the heating may be activated only when the apparatus is connected to a charger or alternatively when a charge level of a battery used by the apparatus is above a threshold level .

The further electrical arrangement 24 may in other examples result in the absorption of water, by for example, releasing a water absorbing compound such as silica gel into the conductive solution 20.

FIG. 6A illustrates another example of a suitable mechanical arrangement 2C. This arrangement is similar to that illustrated in FIG. 4A (or 5A) except that the aperture 16 in a housing 14 is sealed using a membrane 32 that is selective to different phases of water.

In this example, the membrane 32 allows water vapor to pass through it but it does not allow water fluid to pass through it. An example of a suitable material for the membrane 32 is Goretex (Trade mark).

The housing 14 may also comprise a compound 30 that readily absorbs and then dissolves in atmospheric moisture to create a conductive solution 34 that interconnects the first electrode 1 and the second electrode 3. The compound 30 used in the sealed housing 14 may be the same as the compound 18 used in the housing 14 of the mechanical arrangement 2B. By using both the mechanical arrangements 2B and 2C it is possible remove false positives due to water entering in gaseous form and condensing on/in both the compounds 18, 30. In the presence of water in gaseous form both mechanical arrangements 2B and 2C would have low resistance whereas in the presence of water in liquid form only the mechanical arrangement 2B would have a low resistance.

An electrical arrangement 24 such as that described with reference to FIG. 5A may promote, when activated, the egress of water vapor.

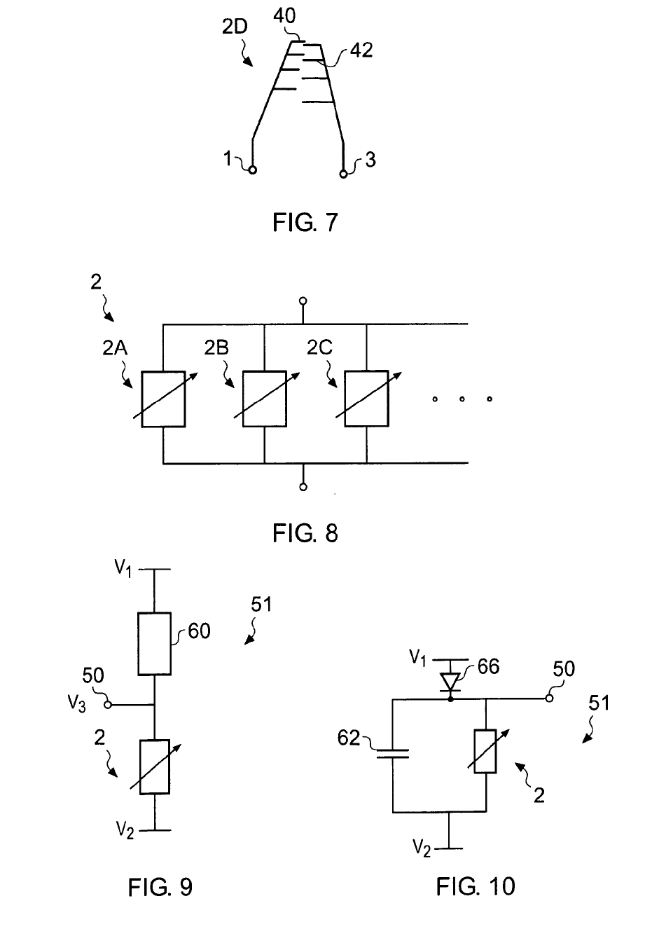

FIG. 7 illustrates an electrical arrangement 2D that comprises a pair of pointed, separated metal electrodes 40, 42. The electrodes may be copper. A constant voltage is provided between the pair of electrodes using, for example, apparatus as illustrated in FIG. 9, 10, 11 or 12. The pair of electrodes maintain their original mechanical configuration in the absence of a corrosive atmosphere. However, after prolonged exposure to a corrosive atmosphere, the pair of electrodes corrode and have a deteriorated, second mechanical configuration.

The pair of electrodes are separated by an air gap that is open to the ambient atmosphere. The air gap used is very small to maintain a high electric field between the pair of electrodes.

Each of the metal electrodes may have prongs like teeth of a comb and the prongs of the respective electrodes are imbricate. The end of one prong faces the end of another prong of the other electrode. This arrangement makes it easier for corrosion to occur especially if the prongs' ends are sharp.

FIG. 8 schematically illustrates how multiple ones of the electrical arrangements 2A, 2B, 2C, 2D may be electrically interconnected as elements in a parallel electrical arrangement 2. The arrangement illustrated may comprise none, one or more of each of the electrical arrangements 2A, 2B, 2C, 2D.

Multiple distinct electrical arrangements are connected in an electrical parallel configuration. Each electrical arrangement 2A, 2B, 2C, 2D has a high resistance between a pair of electrodes 1, 3 in the absence of water and has a low resistance between the pair of electrodes 1, 3 in the presence of water.

Thus a drop in the resistance of any one of the parallel elements in the parallel configuration results in a drop in the resistance of the parallel configuration The detecting electrical arrangement 51 is configured to detect a drop in the resistance of the electrical parallel configuration.

FIG. 9 schematically illustrates an example of an apparatus comprising an electrical arrangement 2 and a detecting electrical arrangement 51 configured to detect a change in the resistance of the electrical arrangement 2. The electrical arrangement 2 may be a single element or a configuration of parallel connected elements.

The detecting arrangement 51 is arranged as a voltage divider. An output node 50 is connected via a fixed resistor 60 of value R60 to a voltage V1 and via the electrical arrangement 2 of variable resistance R2 to a voltage V2 that is different to V1. Typically V1 is a positive voltage and voltage V2 is ground.

The voltage V3 at the output node depends upon the value of R2:

V3=V2+(V1−V2)*R2/(R2+R60)

When the value of R2 drops after water ingress to the electrical arrangement 2, the voltage at the output node 50 drops close to V2.

FIG. 10 schematically illustrates an example of an apparatus comprising an electrical arrangement 2 and a detecting electrical arrangement 51 configured to detect a change in the resistance of the electrical arrangement 2. The electrical arrangement 2 may be a single element or a configuration of parallel connected elements.

The detecting arrangement 51 has an output node 50 connected via a diode 66 to a voltage V1 and via the electrical arrangement 2 to a voltage V2 that is different to V1. A capacitor 62 is connected in parallel to the electrical arrangement 2 between the output node 50 and the voltage V2.

The voltage at the output node 50 drops to V2 when the resistance of the electrical arrangement 2 drops after water ingress to the electrical arrangement 2.

The reference capacitor 62 of the detecting electrical arrangement 51 maintains a constant reference voltage at the output node 50 until the resistance of the electrical arrangement 2 drops even in the absence of the voltage V1. This enable this detecting electrical arrangement to operate in the absence of a power supply V1.

The diode 66 may be connected directly to a battery. There may be circuitry that intermittently connects the diode 66 directly to a battery. The diode 66 may have a low reverse leakage current to inhibit discharge of the reference capacitor 62.

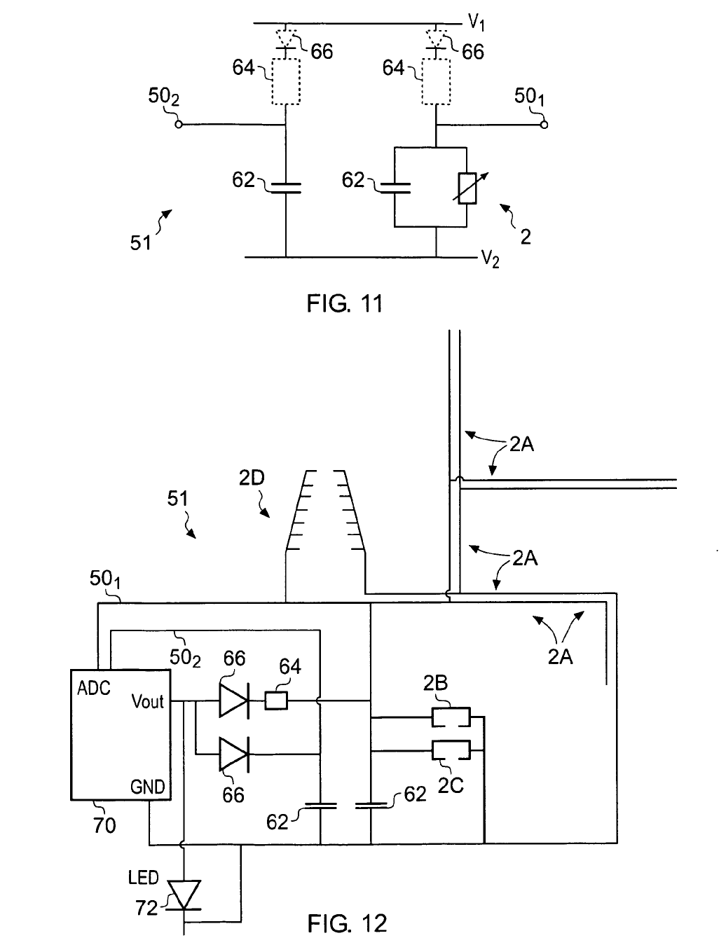

FIG. 11 schematically illustrates an example of an apparatus comprising an electrical arrangement and a differential detecting electrical arrangement 51 configured to detect a change in the resistance of the electrical arrangement 2. The electrical arrangement 2 may be a single element or a configuration of parallel connected elements.

The differential detecting electrical arrangement 51 comprises two parallel parts.

A first part has a first output node 50₁ connected to a voltage V1 and via the electrical arrangement 2 to a voltage V2 that is different to V1. A capacitor 62 is connected in parallel to the electrical arrangement 2 between the first output node 50₁ and the voltage V2.

A second part has a second output node 50₂ connected to the voltage V1 and via a capacitor 62 to the voltage V2.

When the resistance of the electrical arrangement 2 is high before water ingress to the electrical arrangement 2, the first output node 50₁ and the second output node 50₂ provide the same output voltage as determined by the charged reference capacitor 62 of the respective first and second parts.

When the resistance of the electrical arrangement 2 drops after water ingress to the electrical arrangement 2, the voltage at the first output node 50₁ drops to V2 (e.g. earth) and the voltage at the second output node 50₂ becomes relatively greater than the voltage at the first output node 50₁ and the differential in the voltages at the first and second output nodes can be detected. The voltage at the second output node 50₂ is determined by the charged reference capacitor 62 of the second part.

In the absence of voltage V1 for a prolonged period of time parasitic currents will eventually drain both the reference capacitors 61, 62 of the first and second parts. False positives may be avoided by, for example, requiring the voltage at the second output node 50₂ to be above a threshold before a positive is declared and by, for example, ensuring that the reference capacitors 61, 62 drain, in the absence of voltage V1, at approximately the same rate.

The first output node 50₁ may be connected to the voltage V1 via an optional resistor 64 and an optional diode 66. The second output node 50₂ may be connected to the voltage V1 via an optional resistor 64 and an optional diode 66. Whatever the arrangement of the first and second parts it may be desirable to maintain symmetry between the first part and the second part so that they use the same components. This results in the first output node 50₁ and the second output node 50₂ providing the same output voltage when the resistance of the electrical arrangement 2 is high before water ingress to the electrical arrangement 2.

FIG. 12 schematically illustrates an apparatus that has a similar configuration of the electrical arrangement 2 and differential detecting electrical arrangement 51 as illustrated in FIG. 11. In the illustrated example, the first part comprises an electrical arrangement 2 connected between the first output node 50₁ and V2 (GND) in parallel with capacitor 62 and a diode 66 and resistor 64 connected in series between the first output node 50₁ and V1 (Vout). The electrical arrangement 2 of the first part is a configuration of parallel connected elements 2A, 2B, 2C, 2D.

The second part comprises a capacitor 62 connected between the second output node 50₂ and V2 (GND) and a diode 66 connected between the second output node 50₂ and V1 (Vout).

Water ingress at any one of the electro-mechanical arrangements 2A, 2B, 2C, 2D results in a resistance drop of the electrical arrangement 2 and the establishment of a voltage difference between the first output node 50₁ and the second output node 50₂.

In this example, the apparatus comprises a light emitting diode (LED) 72 and LED control circuitry 70 that is configured to drive the LED 72. The apparatus re-uses the LED control circuitry 70 to provide the voltages Vout and GND.

The resistor 64 is a high value to prevent variations in the resistance of the first electrical arrangement 2 affecting the operation of the LED 72.

The LED control circuitry 70 comprises analogue to digital circuitry (ADC) configured to convert an analogue output from the detecting electrical arrangement 51 to a digital value.

Although LED control circuitry has been re-used in this example, it should be appreciated that in other embodiments alternative voltage drivers and/or analogue to digital circuitry may be re-used.

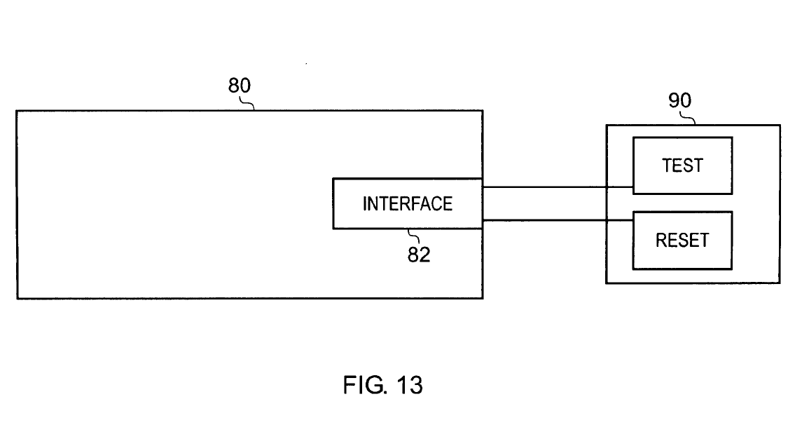

FIG. 13 schematically illustrates an electronic device 80 that comprises an interface 82 that enables an external device 90 to test the apparatus for water ingress. The interface 82 enables the external device 90 to read the voltage value (or its digital equivalent) from, for example, the output node(s) 50, 50₁, 50₂ of the detecting electrical arrangement 51.

The interface 82 may enable the external device 90 to re-set an electrical arrangement 2 after water ingress by providing a voltage or signal that activates the further electrical arrangement 24. This promotes the removal of water from the electrical arrangement 2.

The electronic device 80 may be a portable electronic device such as a mobile cellular telephone, personal digital assistant, personal music player, game console etc or a module for such a device. As used here ‘module’ refers to a unit or apparatus that excludes certain parts/components that would be added by an end manufacturer or a user.

The electronic device may comprise a single detecting electrical arrangement 51 or a plurality of detecting electrical arrangements 51.

It may for example be desirable to provide one detecting electrical arrangement 51 for use in combination with one or more of the mechanical arrangements 2A, 2B. This detecting electrical arrangement 51 then detects water ingress. Water ingress may therefore be identified externally without opening the device via the interface 82 when the voltage at an output node or the differential output at the output nodes exceeds a first threshold. Typically water ingress voids a warranty for the electronic device 80.

The absence of water ingress may be identified externally without opening the device via the interface 82 when the voltage at an output node or the differential output at the output nodes does not exceed a second threshold. The second threshold may be the same as the first threshold or may be less than the first threshold.

It may for example be desirable to provide another detecting electrical arrangement 51 for use in combination with one or more mechanical arrangements 2C. This detecting electrical arrangement 51 then detects water vapor ingress but not water fluid ingress. Water vapor ingress may therefore be identified externally without opening the device via the interface 82 when the voltage at an output node or the differential output at the output nodes exceeds a threshold. Typically water vapor ingress does not void a warranty for the electronic device 80.

The electronic device therefore has an electrical and mechanical arrangement configured to detect voiding of a warranty by electrically identifying water ingress. The electrical and mechanical arrangement is configured to discriminate between water fluid ingress and water vapor ingress.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/we claim:

1. An apparatus comprising:
a first electrical arrangement that has a first resistance between a first electrode and a second electrode in the absence of water and has a second resistance between the first electrode and the second electrode in the presence of water;
a mechanical arrangement configured to maintain the presence of water at the first electrical arrangement; and
a detecting electrical arrangement configured to detect a change in the resistance of the first electrical arrangement.

2. An apparatus as claimed in claim 1, wherein the mechanical arrangement comprises the arrangement of the first electrode in parallel with the second electrode to define therebetween a volume that retains water.

3. (canceled)

4. An apparatus as claimed in claim 1, wherein the mechanical arrangement comprises a substantially enclosed housing having an aperture sized to enable the ingress of water and restrict the evaporation of water.

5. An apparatus as claimed in claim 4, wherein housing comprises a soluble salt or soluble salts.

6. An apparatus as claimed in claim 1, comprising a further electrical arrangement configured to operate as a heater to promote, when activated, the absence of water at 0 the first electrical arrangement

7. (canceled)

8. An apparatus as claimed in claim 1, comprising:
a second electrical arrangement that has a third resistance between a pair of electrodes in the absence of water and has a fourth resistance between the pair of electrodes in the presence of water; and
a second mechanical arrangement comprising a substantially enclosed second housing having an aperture, wherein the aperture is configured to enable the ingress of water in one of a liquid or gaseous phase and restrict the ingress of water in the other of the liquid or gaseous phase.

9. An apparatus as claimed in claim 8, wherein the detecting electrical arrangement is configured to detect a change in the resistance of the first electrical arrangement or the second electrical arrangement.

10. An apparatus as claimed in claim 8, comprising a second detecting electrical arrangement configured to detect a change in the resistance of the second electrical arrangement.

11. An apparatus as claimed in claim 10, wherein the aperture is configured to enable the ingress of water vapor and restrict the ingress of liquid water and wherein the apparatus is configured to discriminate between water fluid ingress and water vapor ingress.

12. An apparatus as claimed in claim 8, wherein the second housing comprises a highly soluble salt or highly soluble salts.

13. An apparatus as claimed in claim 8, wherein the aperture of the second mechanical arrangement is covered by a membrane.

14. An apparatus as claimed in claim 8, comprising a further electrical arrangement configured to encourage, when activated, the absence of water vapor at the second electrical arrangement.

15. An apparatus as claimed in claim 1 comprising a third electrical arrangement configured to provide a constant voltage between a pair of pointed, separated electrodes, wherein the pair of electrodes have a first mechanical configuration in the absence of a corrosive atmosphere and have a deteriorated, second mechanical configuration after prolonged exposure to a corrosive atmosphere.

16-21. (canceled)

22. An apparatus as claimed in claim 1, wherein the apparatus comprises an light emitting diode and light emitting diode control circuitry that is configured to drive the light emitting diode , wherein the apparatus re-uses the light emitting diode control circuitry to provide a voltage to the first electrical arrangement.

23. An apparatus as claimed in claim 22, wherein the first electrical arrangement is serially connected to a high value resistor to prevent variations in the resistance of the first electrical arrangement affecting the operation of the light emitting diode.

24. An apparatus as claimed in claim 23, wherein the light emitting diode control circuitry is configured to convert an analogue output from the detecting electrical arrangement to a digital value.

25-34. (canceled)

35. An apparatus comprising: a third electrical arrangement configured to provide a constant voltage between pairs of separated electrodes, wherein the pairs of electrodes have a first mechanical configuration in the absence of a corrosive atmosphere and have a deteriorated, second mechanical configuration after prolonged exposure to a corrosive atmosphere.

36. An apparatus comprising: an electrical and mechanical arrangement configured to detect voiding of a warranty by electrically identifying water ingress.

37. An apparatus as claimed in claim 36, wherein the electrical and mechanical arrangement is configured to discriminate between water fluid ingress and water vapor ingress.

38. An apparatus as claimed in claim 36, wherein the electrical and mechanical arrangement is configured to discriminate prolonged exposure to corrosive atmosphere.

39. (canceled)
